(19) United States
(12) Patent Application Publication
(10) Pub. No.: US 2015/0364438 A1
(43) Pub. Date: Dec. 17, 2015

(54) BALANCED CURRENT DISTRIBUTION STRUCTURE FOR LARGE CURRENT DELIVERY

(71) Applicant: QUALCOMM Incorporated, San Diego, CA (US)

(72) Inventors: Haiyong XU, San Diego, CA (US); Manoj Ashok KAKADE, San Diego, CA (US); Hua GUAN, San Diego, CA (US); Yue LI, San Diego, CA (US); Xiaoming CHEN, San Diego, CA (US); Ruey Kae ZANG, San Diego, CA (US)

(21) Appl. No.: 14/303,465

(22) Filed: Jun. 12, 2014

(51) Int. Cl. H01L 23/00; B23K 3/06

(52) U.S. Cl. CPC H01L 24/14; H01L 24/11; H01L 24/75; B23K 3/0623; H01L 2924/301; H01L 2224/1412

(57) ABSTRACT

Methods and apparatuses for balancing current delivery. The method couples a low resistance portion of a ball grid array (BGA) to an input portion by at least two vias forming a three-dimensional section. The method couples at least one ball of the BGA to the low resistance portion over a narrow trace.

### BACKGROUND OF THE INVENTION

1. Field of the Invention

Disclosed embodiments relate to balancing current distribution structures.

2. Description of the Related Art

Power management integrated circuits (PMIC's) are circuits specifically designed to manage the power consumption of a system. In particular, a PMIC may process the raw voltage from a power supply, such as a battery, and in turn supply regulated voltages to drive a plurality of off-chip power consumption entities separate from the PMIC. Modern PMIC's are becoming increasingly integrated due to greater system complexity. A typical PMIC may include many high-power on-chip modules for driving off-chip power consumption entities, such as switched-mode battery chargers (SMBC's), back light display drivers (WLED's), buck regulators, audio amplifiers, and flash LED drivers. The on-chip modules may dissipate considerable power when processing power to or from the off-chip entities.

Semiconductor integrated circuit chips can be connected in order to enable them to interact electrically with the outside world. A ball grid array (BGA) semiconductor chip package can employ a plurality of solder balls as external terminals. BGA packages are used to permanently mount devices such as microprocessors. A BGA can provide more interconnection pins than a dual in-line or flat package. The whole bottom surface of the device can be used, instead of just the perimeter. The leads on a BGA can be shorter than with a perimeter-only type.

Power management integrated circuits (PMIC) products can have higher current requirement. Several balls can be used to share the current. By balancing current equally on each ball, the number of BGA balls used may be minimized.

### SUMMARY

The disclosure is directed to balancing current distribution structures.

For example, an exemplary embodiment is directed to an apparatus comprising: an input portion; a low resistance portion of a ball grid array (BGA) coupled to the input portion by at least two vias forming a three-dimensional section; and at least one ball of the BGA coupled to the low resistance portion over a narrow trace.

Another exemplary embodiment is directed to a method for balancing current delivery, the method comprising: coupling a low resistance portion of a ball grid array (BGA) to an input portion by at least two vias forming a three-dimensional section; and coupling at least one ball of the BGA to the low resistance portion over a narrow trace.

Still another exemplary embodiment is directed to an apparatus comprising: means for coupling a low resistance portion of a ball grid array (BGA) to an input portion by at least two vias forming a three-dimensional section; and means for coupling at least one ball of the BGA to the low resistance portion over a narrow trace.

Some advantages to the present disclosure include resistance from a first ball to a second ball of the array can be higher than resistance in other parts of the BGA. The increased resistance can limit the first ball current. Some embodiments can increase package reliability. Because the number of balls and vias is less than in prior art versions, there can be an increase in cost savings.

### BRIEF DESCRIPTION OF THE DRAWINGS

A more complete appreciation of aspects of the disclosure and many of the attendant advantages thereof will be readily obtained as the same becomes better understood by reference to the following detailed description when considered in connection with the accompanying drawings which are presented solely for illustration and not limitation of the disclosure, and in which:

FIG. 1 illustrates an array package connected to a printed circuit board.

FIG. 2 illustrates an example of a two ball apparatus.

FIG. 3 illustrates a circuit representation of a two ball apparatus.

FIG. 4 is a top view of an exemplary four ball apparatus for balancing current delivery.

FIG. 5 is a side view of an exemplary four ball apparatus for balancing current delivery.

FIG. 6 illustrates a circuit diagram of a four ball apparatus for balancing current delivery.

FIG. 7 illustrates an embodiment that can include a method for balancing current delivery.

FIG. 8 illustrates an exemplary method for balancing current delivery.

FIG. 9 illustrates an exemplary system having a four ball apparatus for balancing current delivery.

### DETAILED DESCRIPTION

Various aspects are disclosed in the following description and related drawings. Alternate aspects may be devised without departing from the scope of the disclosure. Additionally, well-known elements of the disclosure will not be described in detail or will be omitted so as not to obscure the relevant details of the disclosure.

The words “exemplary” and/or “example” are used herein to mean “serving as an example, instance, or illustration.” Any aspect described herein as “exemplary” and/or “example” is not necessarily to be construed as preferred or advantageous over other aspects. Likewise, the term “aspects of the disclosure” does not require that all aspects of the disclosure include the discussed feature, advantage or mode of operation.

Further, many aspects are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the disclosure may be embodied in a number of different forms, all of which have been contemplated to be within the scope of the claimed subject matter. In addition, for each of the aspects described herein, the corresponding form of any such aspects may be described herein as, for example, “logic configured to” perform the described action.

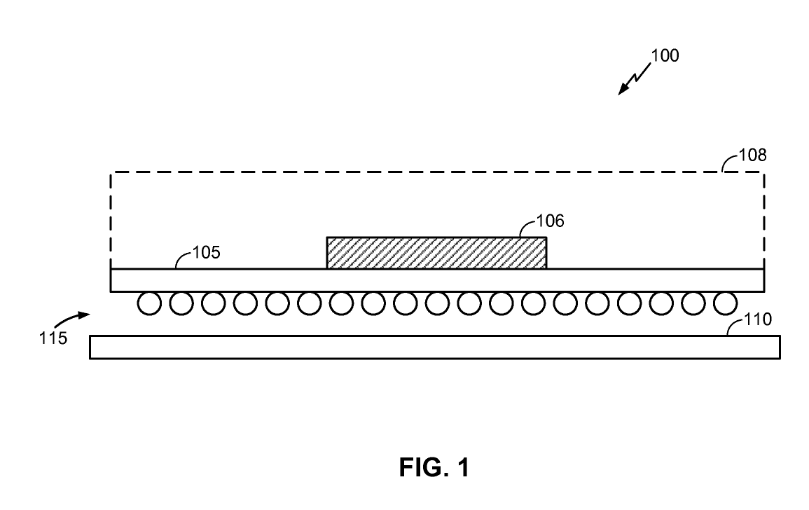

FIG. 1 illustrates an array package 100. The array package 100 includes a substrate 105, a die 106, and optional molding 108. The substrate 105 may be composed of different materials, including ceramic, laminate, or polyimide tape. The die 106 is typically a silicon chip and is connected to the substrate 105. The die 106 may be wire bonded or be flip chip attached to the substrate 105. Molding 108 may be placed around the die 106 to protect the die 106. Molding 108 is typically used when the die 106 is wire bonded to the substrate 105, but may also be used even if the die 106 is flip chip attached or attached by some other method.

The array package 100 is mounted on a printed circuit board (PCB) 110 or similar component. The PCB 110 is typically a laminate. The array package 100 is connected to the PCB 110 by a plurality of solder balls 115. The solder balls 115 may provide both a mechanical and electrical connection between the array package 100 and the PCB 110.

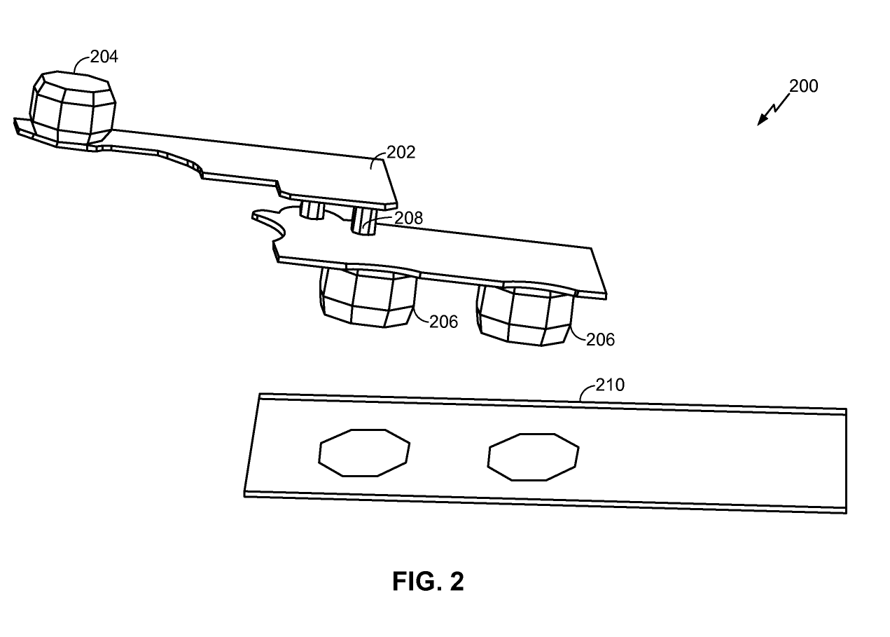

FIG. 2 illustrates an example of a two ball apparatus 200. A package substrate 202 can have an input 204 coupled to a two-ball ball grid array (BGA) 206. The input 204 can be coupled to the BGA 206 by vias 208. The BGA 206 can be coupled to a PCB 210. In some embodiments, the package substrate 202 and the PCB 210 can have approximately the same thickness. In some embodiments, the balls in the BGA 206 can have the same pitch and size. For illustrative purposes, the package substrate 202 and PCB 210 metal thickness can be 18 um. The BGA 206 balls can have a pitch of 500 um and can have a size of 300 um.

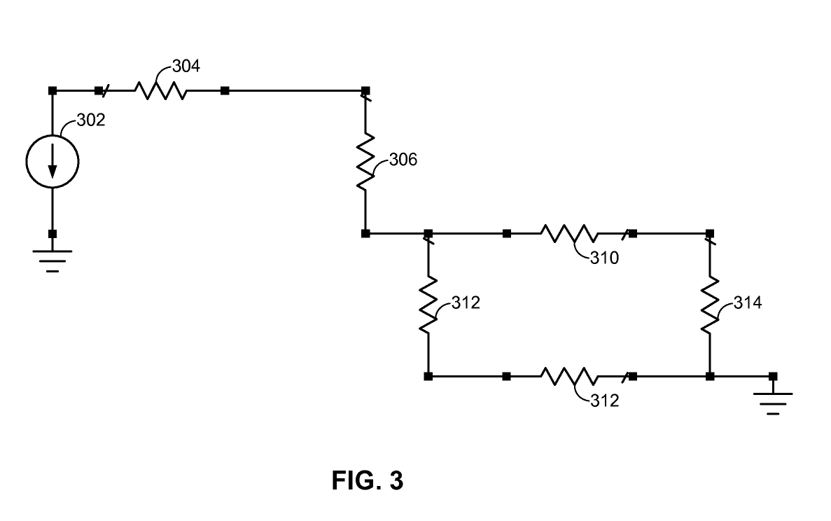

FIG. 3 illustrates a circuit of a two ball apparatus, such as the two ball apparatus 200 in FIG. 2. An input current 302 can be coupled to an input resistance 304, such as input 204. The input resistance 304 can be in series with a via resistance 306, such as the vias 208. The via resistance 306 can be coupled in parallel with a first ball resistance 308 and a package routing resistance 310. The first ball resistance 308 can be in series with a PCB resistance 312. The package routing resistance 310 can be in series with a second ball resistance 314. Both the PCB resistance 312 and the second ball resistance 314 can be connected to ground. In some embodiments, an output current on the first ball resistance 308 and the second ball resistance 314 can be equal when both the package routing resistance 310 and the PCB resistance 312 are equal. For example, if the input current 302 is 1 A, the output current on each ball can be 0.5 A if the package routing resistance 310 and the PCB resistance 312 are equal.

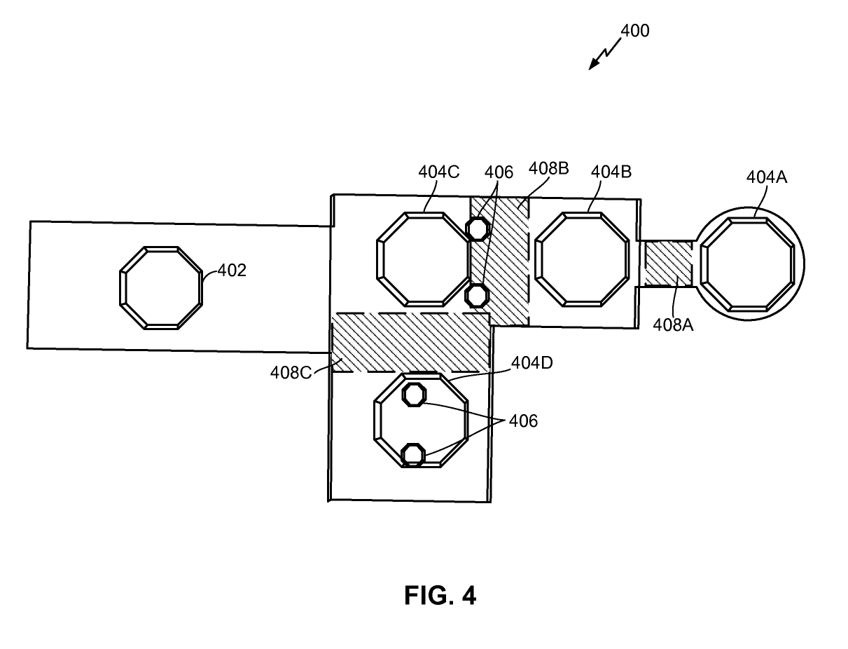

FIG. 4 is a top view of an exemplary four ball apparatus 400. The apparatus 400 can include an input portion 402, a BGA 404, and vias 406. The BGA can include a first ball 404A, a second ball 404B, a third ball 404C, and a fourth ball 404D. As shown, the four ball apparatus 400 can be configured in a three-dimensional section by coupling the input portion 402 to the BGA 404 using the vias 406.

Each ball can have a section between itself and at least one other ball in the BGA 404. In FIG. 4, the first section 408A is smaller in both depth and width than any ball in the BGA 404 whereas the second section 408B and the third section 408C both have a dimension that is wider and/or deeper than the individual balls of the BGA 404. As shown in FIG. 4, the first ball 404A and the second ball 404B have a first section 408A that is narrower than a second section 408B between the second ball 404B and the third ball 404C or a third section 408C between the third ball 404C and the fourth ball 404D. In some embodiments, the resistance in the second section 408B or the third section 408C may be lower than in the first section 408A because of the first section's 408A narrower size. For example, this can allow the first ball 404A to have a lower current than the second ball 404B, the third ball 404C, and the fourth ball 404D. In some embodiments, the BGA 404 can have a low resistance portion coupled to at least one of the balls in the BGA 404. For example, in FIG. 4, a low resistance portion can comprise 408B and 408C. In some embodiments, the input portion can be coupled between the third ball 404C and the fourth ball 404D. In some embodiments, the BGA 404 can be routed in an L-shape. FIG. 4 shows the vias 406 positioned on the fourth ball 404D and close to the third ball 404C.

In one embodiment, current can be input at the input portion 402. The current can be received by the third ball 404C and the fourth ball 404D through vias 406. This current can be shared with the second ball 404B and travel through the first section 408A to the first ball 404A. For example, the narrower width of the first section 408A as compared to the second section 408B and the third section 408C can increase the resistivity of the first section 408A. Thus, the placement of the vias 406 on the fourth ball 404D, the placement of the vias near the third ball 404C, and the width of the first section 408A allow the BGA 404 to balance the current between the four balls.

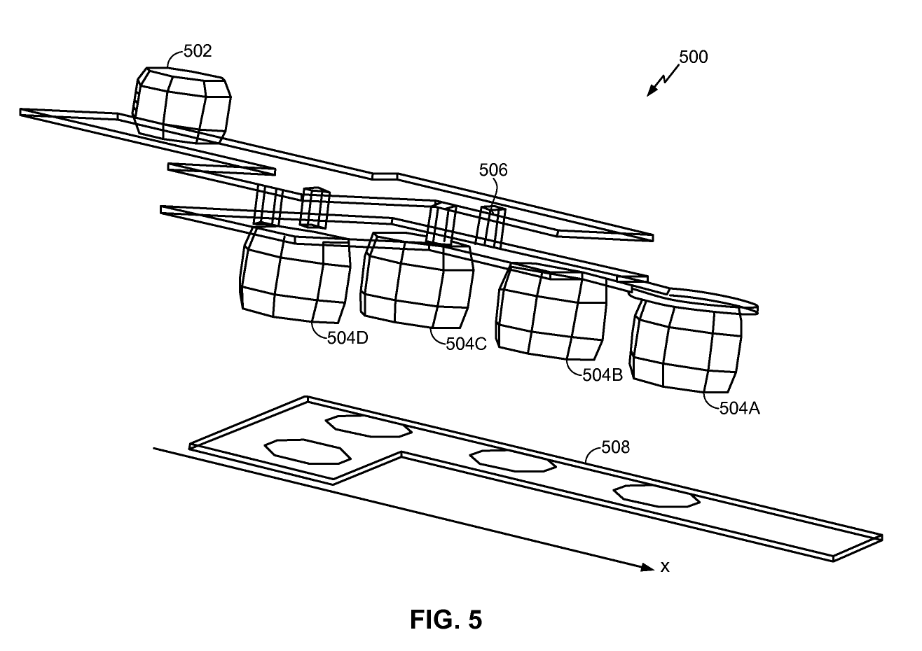

FIG. 5 is a side view of an exemplary four ball apparatus 500. The apparatus 500 can include an input portion 502, a BGA 504, vias 506, and a PCB 508. The BGA can include a first ball 504A, a second ball 504B, a third ball 504C, and a fourth ball 504D. As shown, the four ball apparatus 500 can be configured in a three-dimensional section by coupling the input portion 502 to the BGA 504 using the vias 506.

In some embodiments, the BGA 504 can be routed around a packet edge. In some embodiments, the apparatus 500 can include a flip chip package. In some embodiments, the apparatus 500 can include a wire bond package. For illustrative purposes, the PCB 508 can have a thickness of 18 um. The balls 504A-D can have 500 um pitch and can be 300 um in size. A PCB layout trace can be 400 um wide and 18 um thick.

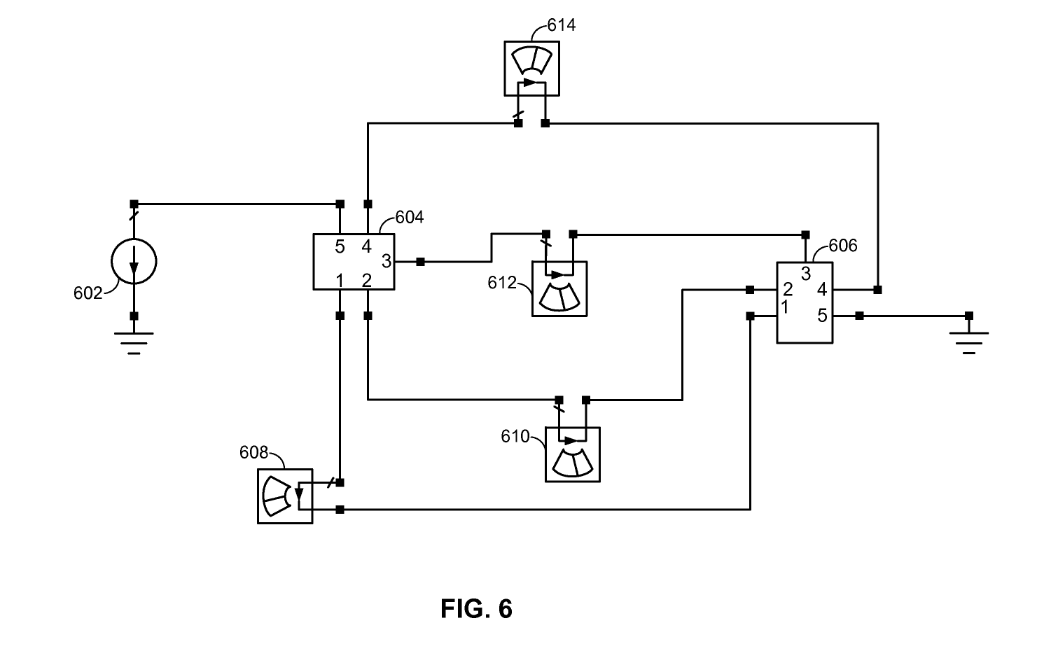

FIG. 6 illustrates a circuit diagram of a four ball apparatus 600. The circuit shows an input 602 and two physical medium attachments (PMA), PMA 604 and PMA 606. PMA 604 and PMA 606 are coupled through four different balls. Each ball's amperage is measured by a probe: probe 1 608, probe 2 610, probe 3 612, and probe 4 614. For example, probe 1 608 may be measuring the first ball 404A in FIG. 4. Likewise, probe 2 610 may be measuring the second ball 404B; probe 3 612 may be measuring the third ball 404C; and probe 4 614 may be measuring the fourth ball 404D.

Table 1 provides exemplary data relating to FIG. 6 when the frequency is at 0 Hz. The variation shown in Table 1 ranges from 720 mA to 770 mA when the current applied is 3 A. This even distribution can assist in increasing reliability across a BGA without requiring more materials (e.g., balls and vias). For example, balancing the current of all the balls below 1.1 A per ball allows the apparatus 600 to remain within electromagnetic specifications. Reducing materials can also reduce costs.

TABLE 1

| | Frequency | | | |
|---|---|---|---|---|
| | 608 | 610 | 612 | 614 |
| 0 Hz | 764.2 mA | 752.5 mA | 761.6 mA | 721.7 mA |

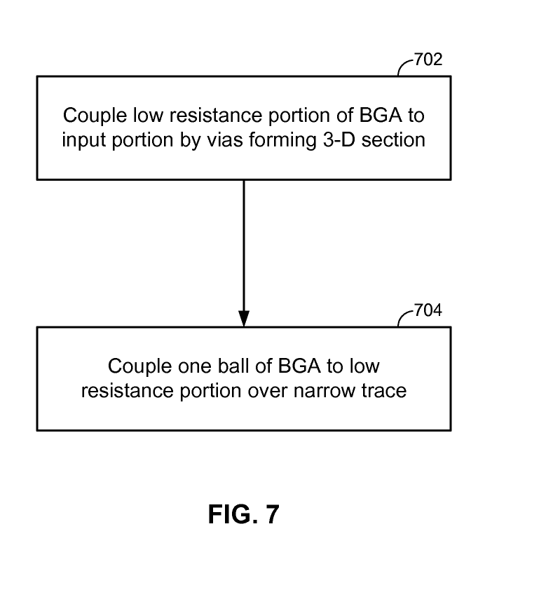

FIG. 7 illustrates an embodiment that can include a method for balancing current delivery: coupling a low resistance portion of a ball grid array (BGA) to an input portion by at least two vias forming a three-dimensional section (e.g., the BGA is comprised of at least four balls; the BGA comprises an L-shaped package routing)—Block 702; coupling at least one ball of the BGA to the low resistance portion over a narrow trace (e.g., a section between a first ball and a second ball of at least four balls is narrower than other routing sections between the at least four balls)—Block 704.

In some embodiments, the at least two vias are positioned close to a third ball of the at least four balls. In some embodiments, the at least two vias are coupled to a fourth ball of the at least four balls. In some embodiments, the input portion is coupled between a third ball of the at least four balls and a fourth ball of the at least four balls.

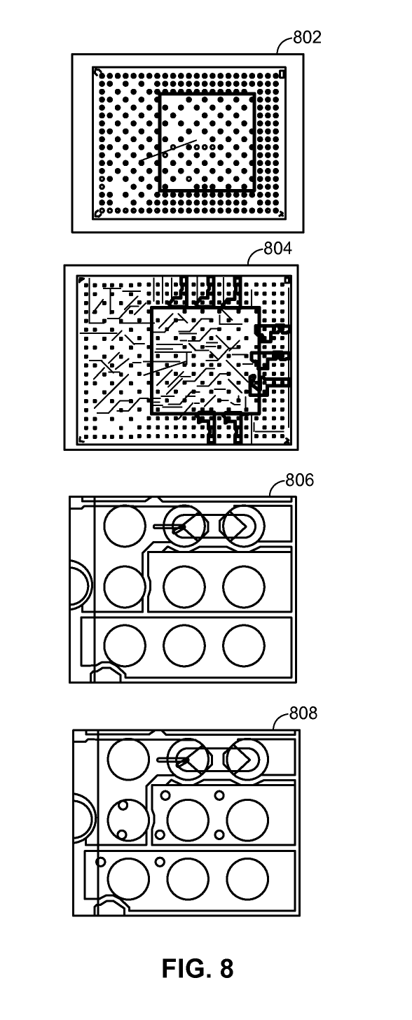

FIG. 8 shows an exemplary method for balancing current delivery. A BGA is created—Block 802. The BGA is routed around a packet edge (e.g., the BGA includes L-shape routing)—Block 804. A first section of the L-shape can be narrower than an input section (e.g., the first section's width can allow for a higher resistance in the first section to help balance current load)—Block 806. Vias can be placed near or on the third and fourth balls (e.g., the vias can be placed in specific locations, shown here as two vias close to the third ball and two vias on the fourth ball, to balance current on the third and fourth balls)—Block 808.

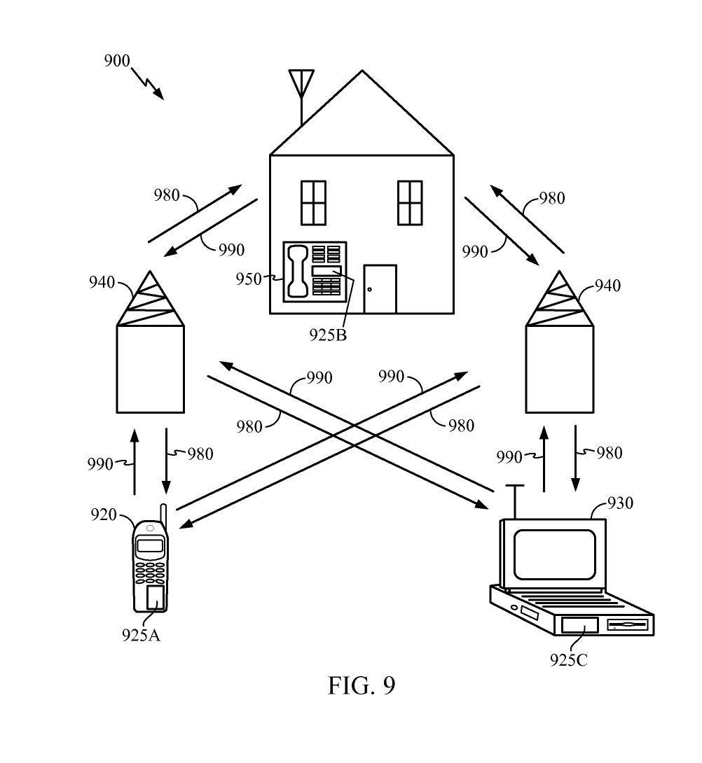

FIG. 9 is a block diagram showing an exemplary wireless communication system 900 in which an embodiment of the disclosure may be advantageously employed. For purposes of illustration, FIG. 9 shows three remote units 920, 930, and 950 and two base stations 940. It will be recognized that wireless communication systems may have many more remote units and base stations. Remote units 920, 930, and 950 include IC devices 925A, 925B and 925C, as disclosed below. It will be recognized that any device containing an IC may also include a four ball apparatus having the disclosed features and/or components manufactured by the processes disclosed here, including the base stations, switching devices, and network equipment. FIG. 9 shows forward link signals 980 from the base station 940 to the remote units 920, 930, and 950 and reverse link signals 990 from the remote units 920, 930, and 950 to base stations 940.

In FIG. 9, the remote unit 920 is shown as a mobile telephone, the remote unit 930 is shown as a portable computer, and the remote unit 950 is shown as a fixed location remote unit in a wireless local loop system. For example, the remote units may be a device such as a music player, a video player, an entertainment unit, a navigation device, a communications device, a personal digital assistant (PDA), a fixed location data unit, and a computer. Although FIG. 9 illustrates remote units according to the teachings of the disclosure, the disclosure is not limited to these exemplary illustrated units. The disclosure may be suitably employed in any device which includes a four ball apparatus, as described above.

Generally, unless stated otherwise explicitly, the phrase “logic configured to” as used throughout this disclosure is intended to invoke an aspect that is at least partially implemented with hardware, and is not intended to map to software-only implementations that are independent of hardware. Also, it will be appreciated that the configured logic or “logic configured to” in the various blocks are not limited to specific logic gates or elements, but generally refer to the ability to perform the functionality described herein (either via hardware or a combination of hardware and software). Thus, the configured logics or “logic configured to” as illustrated in the various blocks are not necessarily implemented as logic gates or logic elements despite sharing the word “logic.” Other interactions or cooperation between the logic in the various blocks will become clear to one of ordinary skill in the art from a review of the aspects described below in more detail.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the aspects disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a general purpose processor, a digital signal processor (DSP), an application specific integrated circuit (ASIC), a field programmable gate array (FPGA) or other programmable logic device, discrete gate or transistor logic, discrete hardware components, or any combination thereof designed to perform the functions described herein. A general purpose processor may be a microprocessor, but in the alternative, the processor may be any conventional processor, controller, microcontroller, or state machine. A processor may also be implemented as a combination of computing devices, e.g., a combination of a DSP and a microprocessor, a plurality of microprocessors, one or more microprocessors in conjunction with a DSP core, or any other such configuration.

The methods, sequences and/or algorithms described in connection with the aspects disclosed herein may be embodied directly in hardware, in a software module executed by a processor, or in a combination of the two. A software module may reside in RAM, flash memory, ROM, EPROM, EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in an electronic object. In the alternative, the processor and the storage medium may reside as discrete components in a user terminal.

In one or more exemplary aspects, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code in the form of instructions or data structures and that can be accessed by a computer. Also, any connection is properly termed a computer-readable medium. For example, if the software is transmitted from a website, server, or other remote source using a coaxial cable, fiber optic cable, twisted pair, DSL, or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes CD, laser disc, optical disc, DVD, floppy disk and Blu-ray disc where disks usually reproduce data magnetically, while discs reproduce data optically with lasers. Combinations of the above should also be included within the scope of computer-readable media.

While the foregoing disclosure shows illustrative aspects of the disclosure, it should be noted that various changes and modifications could be made herein without departing from the scope of the disclosure as defined by the appended claims. The functions, steps and/or actions of the method claims in accordance with the aspects of the disclosure described herein need not be performed in any particular order. Furthermore, although elements of the disclosure may be described or claimed in the singular, the plural is contemplated unless limitation to the singular is explicitly stated.

What is claimed is:

1. An apparatus comprising:
an input portion;
a low resistance portion of a ball grid array (BGA) coupled to the input portion by at least two vias forming a three-dimensional section; and
at least one ball of the BGA coupled to the low resistance portion over a narrow trace.

2. The apparatus of claim 1, wherein the BGA is comprised of at least four balls.

3. The apparatus of claim 2, wherein the at least two vias are positioned close to a third of the at least four balls.

4. The apparatus of claim 2, wherein the at least two vias are coupled to a fourth of the at least four balls.

5. The apparatus of claim 2, wherein the input portion is coupled between a third ball of the at least four balls and a fourth ball of the at least four balls.

6. The apparatus of claim 2, wherein a section between a first ball and a second ball of the at least four balls is narrower than other routing sections between the at least four balls.

7. The apparatus of claim 1, wherein the BGA is routed around a packet edge.

8. The apparatus of claim 1, wherein the BGA comprises an L-shaped package routing.

9. The apparatus of claim 1, further comprising a printed circuit board (PCB).

10. The apparatus of claim 1, further comprising a flip chip package.

11. The apparatus of claim 1, further comprising a wire bond package.

12. A method for balancing current delivery, the method comprising:
coupling a low resistance portion of a ball grid array (BGA) to an input portion by at least two vias forming a three-dimensional section; and
coupling at least one ball of the BGA to the low resistance portion over a narrow trace.

13. The method of claim 12, wherein the BGA is comprised of at least four balls.

14. The method of claim 13, wherein the at least two vias are positioned close to a third of the at least four balls.

15. The method of claim 13, wherein the at least two vias are coupled to a fourth of the at least four balls.

16. The method of claim 13, wherein the input portion is coupled between a third ball of the at least four balls and a fourth ball of the at least four balls.

17. The method of claim 13, wherein a section between a first ball and a second ball of the at least four balls is narrower than other routing sections between the at least four balls.

18. The method of claim 12, wherein the BGA is routed around a packet edge.

19. The method of claim 12, wherein the BGA comprises an L-shaped package routing.

20. An apparatus comprising:
means for coupling a low resistance portion of a ball grid array (BGA) to an input portion by at least two vias forming a three-dimensional section; and
means for coupling at least one ball of the BGA to the low resistance portion over a narrow trace.
